(19) United States
(12) Patent Application Publication
(10) Pub. No.: US 2024/0105902 A1
(43) Pub. Date: Mar. 28, 2024

(54) DISPLAY DEVICE

(71) Applicant: Japan Display Inc., Tokyo (JP)

(72) Inventor: Masanobu IKEDA, Tokyo (JP)

(73) Assignee: Japan Display Inc., Tokyo (JP)

(21) Appl. No.: 18/533,330

(22) Filed: Dec. 8, 2023

Related U.S. Application Data
(63) Continuation of application No. PCT/JP2022/020279, filed on May 13, 2022.

(30) Foreign Application Priority Data
Jul. 12, 2021 (JP) 2021-115079

(51) Int. Cl. H01L 33/64; H01L 25/16; H01L 27/15; H01L 33/00; H01L 33/06; H01L 33/62

(52) U.S. Cl. CPC H01L 33/647; H01L 25/167; H01L 27/156; H01L 33/0008; H01L 33/06; H01L 33/62

(57) ABSTRACT

A display device includes a substrate, a heat dissipation layer provided to a main surface of the substrate and including aluminum nitride, a plurality of light-emitting elements provided on the heat dissipation layer on the main surface of the substrate, an insulating film covering the heat dissipation layer, and cathode wiring provided on the insulating film in a peripheral region outside a display region of the substrate and electrically coupled to a cathode of the light-emitting elements. The heat dissipation layer is continuously provided from a region overlapping the light-emitting elements to the peripheral region, and the insulating film has a contact hole overlapping the cathode wiring and the heat dissipation layer in plan view from a direction perpendicular to the main surface of the substrate.

### CROSS-REFERENCE TO RELATED APPLICATION

This application is a continuation of International Patent Application No. PCT/JP2022/020279 filed on May 13, 2022, which designates the United States, incorporated herein by reference, and which claims the benefit of priority from Japanese Patent Application No. 2021-115079 filed on Jul. 12, 2021, incorporated herein by reference.

### BACKGROUND

### 1. Technical Field

The present invention relates to a display device.

### 2. Description of the Related Art

Display devices provided with micro-sized light-emitting diodes (micro LEDs) as display elements have been attracting attention (refer to WO 2020/188851 and Japanese Translation of PCT International Application Publication No. 2021-508175 (JP-T-2021-508175), for example). WO 2020/188851 describes a display device (referred to as an LED display in WO 2020/188851) in which light-emitting elements and transistors that drive the light-emitting elements are formed on the same surface of a glass substrate. JP-T-2021-508175 describes a light-emitting element with a tunnel junction layer.

Inorganic light-emitting diodes decrease the luminous efficiency as the temperature rises. Therefore, display devices with inorganic light-emitting diodes may possibly decrease the luminance as the temperature rises, resulting in deteriorated display characteristics.

An object of the present invention is to provide a display device that can suppress deterioration of display characteristics.

### SUMMARY

A display device according to an embodiment of the present disclosure includes a substrate, a heat dissipation layer provided to a main surface of the substrate and including aluminum nitride, a plurality of light-emitting elements provided on the heat dissipation layer on the main surface of the substrate, an insulating film covering the heat dissipation layer, and cathode wiring provided on the insulating film in a peripheral region outside a display region of the substrate and electrically coupled to a cathode of the light-emitting elements. The heat dissipation layer is continuously provided from a region overlapping the light-emitting elements to the peripheral region, and the insulating film has a contact hole overlapping the cathode wiring and the heat dissipation layer in plan view from a direction perpendicular to the main surface of the substrate.

### BRIEF DESCRIPTION OF THE DRAWINGS

FIG. 1 is a plan view schematically illustrating a display device according to a first embodiment;

FIG. 2 is a plan view of a plurality of pixels;

FIG. 3 is a circuit diagram of a pixel circuit;

FIG. 4 is a sectional view along line IV-IV′ of FIG. 1;

FIG. 5 is a graph of temperature characteristics of a light-emitting element;

FIG. 6 is a sectional view of a schematic sectional configuration of the display device according to a second embodiment;

FIG. 7 is a sectional view of a schematic sectional configuration of the light-emitting element according to a third embodiment; and

FIG. 8 is a circuit diagram of the pixel circuit according to the third embodiment.

### DETAILED DESCRIPTION

Exemplary aspects (embodiments) to embody the present invention are described below in greater detail with reference to the accompanying drawings. The contents described in the embodiments below are not intended to limit the present invention. Components described below include components easily conceivable by those skilled in the art and components substantially identical therewith. Furthermore, the components described below may be appropriately combined. What is disclosed herein is given by way of example only, and appropriate modifications made without departing from the spirit of the present invention and easily conceivable by those skilled in the art naturally fall within the scope of the present invention. To simplify the explanation, the drawings may illustrate the width, the thickness, the shape, and other elements of each unit more schematically than an actual aspect. These elements, however, are given by way of example only and are not intended to limit interpretation of the present invention. In the present specification and the drawings, components similar to those previously described with reference to previous drawings are denoted by like reference numerals, and detailed explanation thereof may be appropriately omitted.

To describe an aspect where a first structure is disposed on a second structure in the present specification and the claims, the term “on” includes both of the following cases unless otherwise noted: a case where the first structure is disposed directly on the second structure in contact with the second structure, and a case where the first structure is disposed on the second structure with another structure interposed therebetween.

### First Embodiment

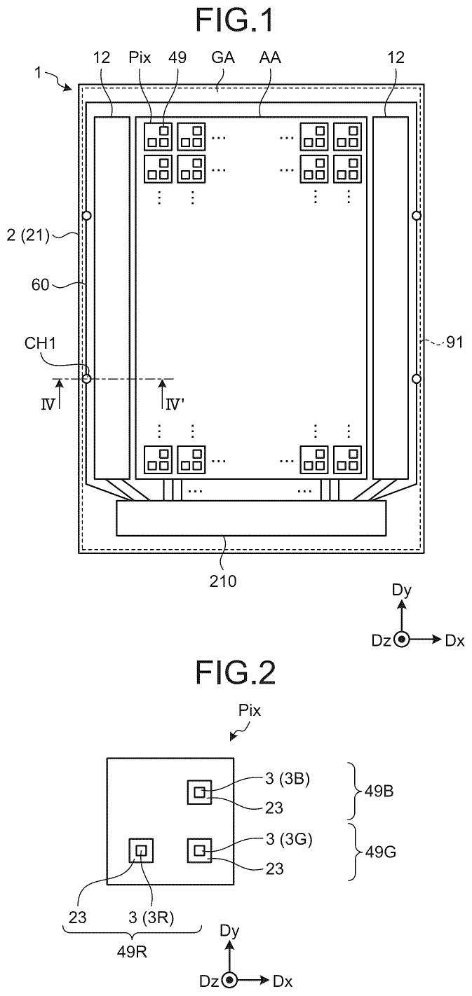

FIG. 1 is a plan view schematically illustrating a display device according to a first embodiment. As illustrated in FIG. 1, a display device 1 includes an array substrate 2, a plurality of pixels Pix, a drive circuit 12, a drive integrated circuit (IC) 210, cathode wiring 60, and a heat dissipation layer 91. The array substrate 2 is a drive circuit substrate for driving the pixels Pix and is also called a backplane or an active matrix substrate. The array substrate 2 includes a substrate 21, a plurality of transistors, a plurality of capacitances, various kinds of wiring, and other components.

As illustrated in FIG. 1, the display device 1 has a display region AA and a peripheral region GA. The display region AA is a region that overlaps the pixels Pix and displays an image. The peripheral region GA is a region not overlapping the pixels Pix and is disposed outside the display region AA.

The pixels Pix are arrayed in a first direction Dx and a second direction Dy in the display region AA of the substrate 21. The first direction Dx and the second direction Dy are parallel to the surface of the substrate 21. The first direction Dx is orthogonal to the second direction Dy. The first direction Dx may intersect the second direction Dy without being orthogonal thereto. A third direction Dz is orthogonal to the first direction Dx and the second direction Dy. The third direction Dz corresponds to the normal direction of the substrate 21, for example. In the following description, plan view indicates the positional relation viewed from the third direction Dz.

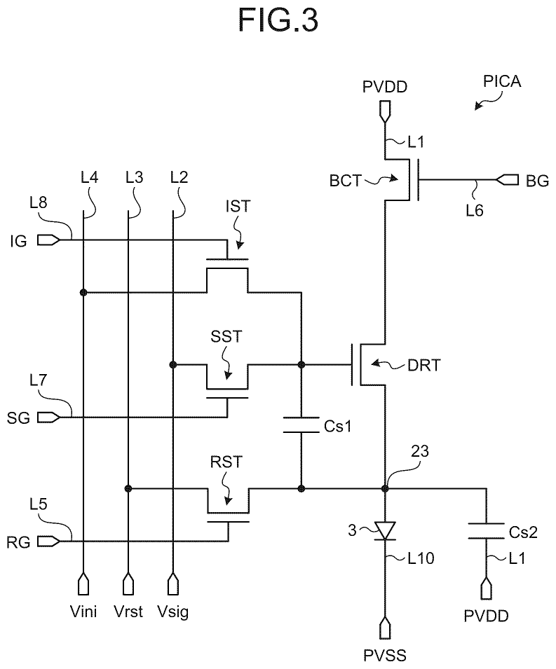

The drive circuit 12 is a circuit that drives a plurality of gate lines (e.g., a reset control signal line L5, an output control signal line L6, a pixel control signal line L7, and an initialization control signal line L8 (refer to FIG. 3)) based on various control signals supplied via wiring extending from the drive IC 210. The drive circuit 12 sequentially or simultaneously selects a plurality of gate lines and supplies gate drive signals to the selected gate lines. As a result, the drive circuit 12 selects a plurality of pixels Pix coupled to the gate lines.

The drive IC 210 is a circuit that controls display on the display device 1. A plurality of wires extend from the drive IC 210 toward the pixels Pix (e.g., a video signal line L2, a reset power supply line L3, and an initialization power supply line L4 (refer to FIG. 3)). The drive IC 210 is mounted in the peripheral region GA of the substrate 21 as chip on glass (COG). The present embodiment is not limited thereto, and the drive IC 210 may be mounted on a flexible printed circuit board or a rigid board coupled to the peripheral region GA of the substrate 21.

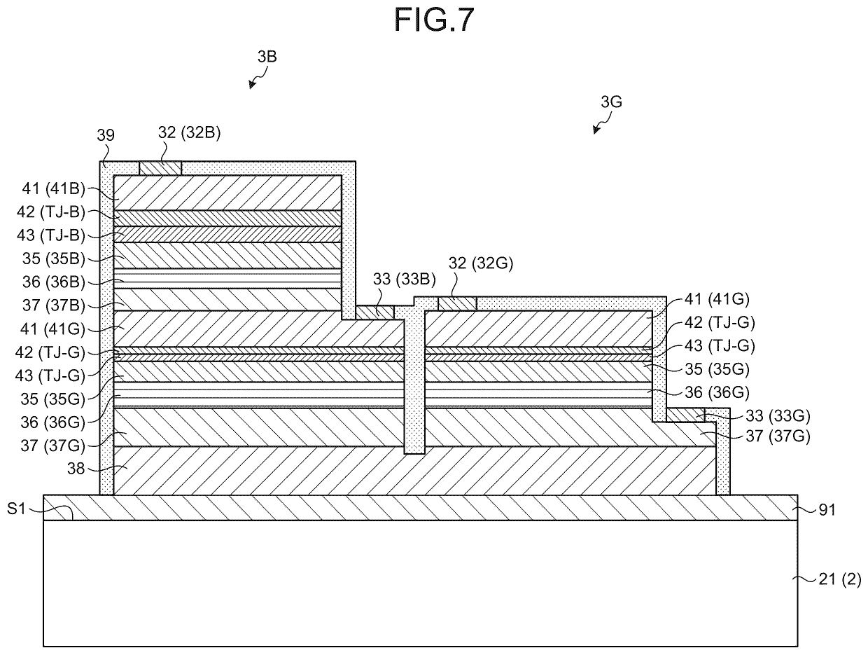

The cathode wiring 60 is provided to the peripheral region GA of the substrate 21. The cathode wiring 60 is provided surrounding the pixels Pix in the display region AA and the drive circuit 12 in the peripheral region GA. The cathodes of a plurality of light-emitting elements 3 are coupled to the common cathode wiring 60 and are supplied with a fixed potential (e.g., a ground potential). More specifically, a cathode electrode 33 (refer to FIG. 7) of the light-emitting element 3 is coupled to the cathode wiring 60 via a cathode coupling wiring (not illustrated) formed on the array substrate 2. The cathode wiring 60 is not limited to single wiring continuously formed along three sides of the substrate 21 and may be composed of two partial wires separated by a slit on any of the sides or wiring disposed along at least one side of the substrate 21.

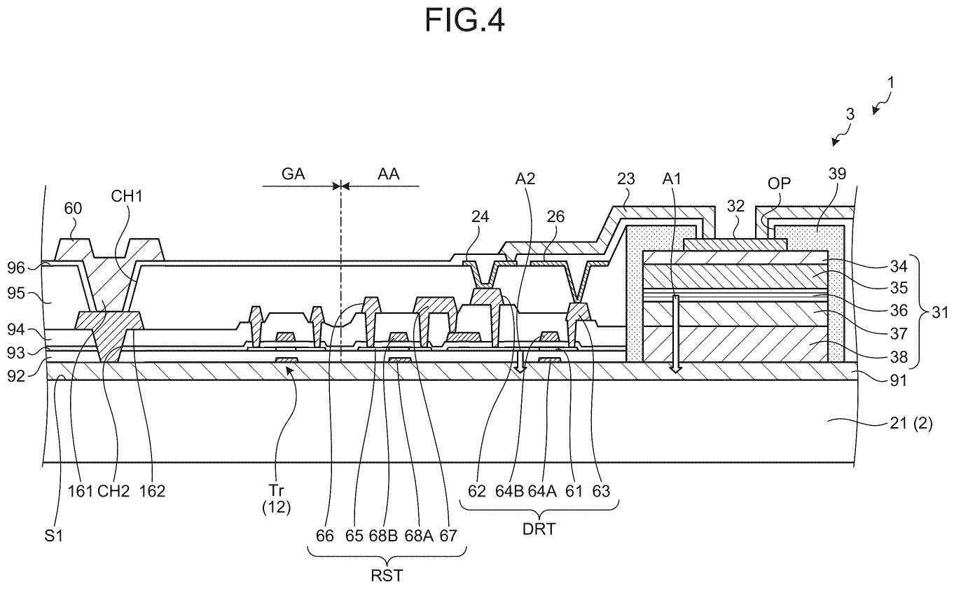

The heat dissipation layer 91 is provided to a main surface S1 (refer to FIG. 4) of the substrate 21 and is provided in a region overlapping the display region AA and the peripheral region GA in plan view. The heat dissipation layer 91 illustrated in FIG. 1 is provided to the entire main surface S1 of the substrate 21 and is provided to a region overlapping the pixels Pix in the display region AA. The heat dissipation layer 91 is provided in the peripheral region GA over a region overlapping the drive circuit 12 and the drive IC 210 serving as peripheral circuits in plan view and a region overlapping the cathode wiring 60 in plan view. The heat dissipation layer 91 is coupled to the cathode wiring 60 through a plurality of contact holes CH1 in the peripheral region GA. The configuration of the heat dissipation layer 91 and the cathode wiring 60 will be described later in greater detail. The heat dissipation layer 91 is not necessarily provided to the entire main surface S1 of the substrate 21 and may not be provided to part of the display region AA and the peripheral region GA.

FIG. 2 is a plan view of a plurality of pixels. As illustrated in FIG. 2, one pixel Pix includes a plurality of sub-pixels 49. The pixel Pix includes a sub-pixel 49R, a sub-pixel 49G, and a sub-pixel 49B, for example. The sub-pixel 49R displays a primary color of red as the first color. The sub-pixel 49G displays a primary color of green as the second color. The sub-pixel 49B displays a primary color of blue as the third color. As illustrated in FIG. 2, in one pixel Pix, the sub-pixel 49R and the sub-pixel 49G are adjacently disposed in the first direction Dx. The sub-pixel 49G and the sub-pixel 49B are adjacently disposed in the second direction Dy. The first color, the second color, and the third color are not limited to red, green, and blue, respectively, and may be any desired colors, such as complementary colors. In the following description, the sub-pixel 49R, the sub-pixel 49G, and the sub-pixel 49B are referred to as the sub-pixels 49 when they need not be distinguished from one another.

The sub-pixels 49 each include the light-emitting element 3 and an anode wiring 23. The display device 1 displays an image by causing a light-emitting element 3R, a light-emitting element 3G, and a light-emitting element 3B in the sub-pixel 49R, the sub-pixel 49G, and the sub-pixel 49B, respectively, to output different light. The light-emitting element 3 is an inorganic light-emitting diode (LED) chip having a size of approximately 3 μm to 300 μm in plan view and is called a micro LED. The display device 1 including the micro LEDs in the respective pixels is also called a micro LED display device. The term “micro” of the micro LED is not intended to limit the size of the light-emitting element 3.

The light-emitting elements 3 may output light in four or more different colors. The arrangement of the sub-pixels 49 is not limited to the configuration illustrated in FIG. 2. The sub-pixel 49R, for example, may be adjacent to the sub-pixel 49B in the second direction Dy. Alternatively, the sub-pixels 49R, 49G, and 49B may be repeatedly arrayed in this order in the first direction Dx.

FIG. 3 is a circuit diagram of a pixel circuit. FIG. 3 illustrates a pixel circuit PICA provided to one sub-pixel 49, and the pixel circuit PICA is provided to each of the sub-pixels 49. As illustrated in FIG. 3, the pixel circuit PICA includes the light-emitting element 3, five transistors, and two capacitances. Specifically, the pixel circuit PICA includes a drive transistor DRT, an output transistor BCT, an initialization transistor IST, a pixel selection transistor SST, and a reset transistor RST. The drive transistor DRT, the output transistor BCT, the initialization transistor IST, the pixel selection transistor SST, and the reset transistor RST are each composed of an n-type thin film transistor (TFT). The pixel circuit PICA also includes a first capacitance Cs1 and a second capacitance Cs2.

The cathode (cathode electrode 33 (refer to FIG. 7)) of the light-emitting element 3 is coupled to a cathode power supply line L10. The anode (anode electrode 32) of the light-emitting element 3 is coupled to an anode power supply line L1 via the anode wiring 23, the drive transistor DRT, and the output transistor BCT. The anode power supply line L1 is supplied with an anode power supply potential PVDD. The cathode power supply line L10 is supplied with a cathode power supply potential PVSS via the cathode wiring 60 and the cathode electrode 33. The anode power supply potential PVDD is higher than the cathode power supply potential PVSS.

The anode power supply line L1 supplies the anode power supply potential PVDD serving as a drive potential to the sub-pixel 49. Specifically, the light-emitting element 3 ideally emits light by being supplied with a forward current (drive current) due to the potential difference between the anode power supply potential PVDD and the cathode power supply potential PVSS (PVDD−PVSS). In other words, the anode power supply potential PVDD has a potential difference that causes the light-emitting element 3 to emit light with respect to the cathode power supply potential PVSS. The anode electrode 32 of the light-emitting element 3 is electrically coupled to the anode wiring 23, and the second capacitance Cs2 is formed between the anode wiring 23 and the anode power supply line L1.

The source electrode of the drive transistor DRT is coupled to the anode electrode 32 of the light-emitting element 3 via the anode wiring 23, and the drain electrode is coupled to the source electrode of the output transistor BCT. The gate electrode of the drive transistor DRT is coupled to the first capacitance Cs1, the drain electrode of the pixel selection transistor SST, and the drain electrode of the initialization transistor 1ST.

The gate electrode of the output transistor BCT is coupled to the output control signal line L6. The output control signal line L6 is supplied with output control signals BG. The drain electrode of the output transistor BCT is coupled to the anode power supply line L1.

The source electrode of the initialization transistor 1ST is coupled to the initialization power supply line L4. The initialization power supply line L4 is supplied with an initialization potential Vini. The gate electrode of the initialization transistor IST is coupled to the initialization control signal line L8. The initialization control signal line L8 is supplied with initialization control signals IG. In other words, when the initialization transistor IST is turned on, the gate electrode of the drive transistor DRT is coupled to the initialization power supply line L4 via the initialization transistor IST.

The source electrode of the pixel selection transistor SST is coupled to the video signal line L2 The video signal line L2 is supplied with video signals Vsig. The gate electrode of the pixel selection transistor SST is coupled to the pixel control signal line L7. The pixel control signal line L7 is supplied with pixel control signals SG.

The source electrode of the reset transistor RST is coupled to the reset power supply line L3. The reset power supply line L3 is supplied with a reset power supply potential Vrst. The gate electrode of the reset transistor RST is coupled to the reset control signal line L5. The reset control signal line L5 is supplied with reset control signals RG. The drain electrode of the reset transistor RST is coupled to the anode wiring 23 (anode electrode 32 of the light-emitting element 3) and the source electrode of the drive transistor DRT. The reset operation of the reset transistor RST resets the voltage held in the first capacitance Cs1 and the second capacitance Cs2.

The first capacitance Cs1 is formed between the drain electrode of the reset transistor RST and the gate electrode of the drive transistor DRT. The pixel circuit PICA can suppress fluctuations in the gate voltage due to a parasitic capacitance of the drive transistor DRT and a leakage current by the first capacitance Cs1 and the second capacitance Cs2.

In the following description, the anode power supply line L1 and the cathode power supply line L10 may be simply referred to as power supply lines. The video signal line L2, the reset power supply line L3, and the initialization power supply line L4 may be referred to as signal lines. The reset control signal line L5, the output control signal line L6, the pixel control signal line L7, and the initialization control signal line L8 may be referred to as gate lines.

The gate electrode of the drive transistor DRT is supplied with a potential corresponding to the video signal Vsig (or gradation signal). In other words, the drive transistor DRT supplies an electric current corresponding to the video signal Vsig to the light-emitting element 3 based on the anode power supply potential PVDD supplied via the output transistor BCT. Thus, the anode power supply potential PVDD supplied to the anode power supply line L1 is lowered by the drive transistor DRT and the output transistor BCT. As a result, the anode electrode 32 of the light-emitting element 3 is supplied with a potential lower than the anode power supply potential PVDD.

A first electrode of the second capacitance Cs2 is supplied with the anode power supply potential PVDD via the anode power supply line L1, and a second electrode of the second capacitance Cs2 is supplied with a potential lower than the anode power supply potential PVDD. In other words, the first electrode of the second capacitance Cs2 is supplied with a higher potential than the second electrode of the second capacitance Cs2. The first electrode of the second capacitance Cs2 is a counter electrode 26 illustrated in FIG. 4, for example, and the second electrode of the second capacitance Cs2 is the anode wiring 23 coupled to the source of the drive transistor DRT illustrated in FIG. 4.

In the display device 1, the drive circuit 12 (refer to FIG. 1) selects a plurality of pixel rows row by row from the first row (e.g., the uppermost pixel row in the display region AA in FIG. 1). The drive IC 210 writes the video signals Vsig (video writing potential) to the sub-pixels 49 in the selected pixel row to cause the light-emitting elements 3 to emit light. The drive IC 210 supplies the video signals Vsig to the video signal line L2, supplies the reset power supply potential Vrst to the reset power supply line L3, and supplies the initialization potential Vini to the initialization power supply line L4 every one horizontal scanning period. The display device 1 repeats these operations for each image of one frame.

Next, a sectional configuration of the display device 1 is described. FIG. 4 is a sectional view along line IV-IV′ of FIG. 1. As illustrated in FIG. 4, the light-emitting element 3 is provided on the array substrate 2. The array substrate 2 includes the substrate 21, various transistors, various wiring, and various insulating films. The substrate 21 is a glass substrate serving as an insulating substrate. The substrate 21 is not limited to a glass substrate and may be a resin substrate or a resin film.

In the present specification, a direction from the substrate 21 toward the light-emitting element 3 in a direction perpendicular to the surface of the substrate 21 is referred to as an “upper side” or simply as “top”. A direction from the light-emitting element 3 to the substrate 21 is referred to as a “lower side” or simply as “bottom”.

The heat dissipation layer 91 is provided covering the main surface S1 of the substrate 21 and is continuously provided from the display region AA to the peripheral region GA of the substrate 21. The heat dissipation layer 91 according to the present embodiment is provided in direct contact with the main surface S1 of the substrate 21. The heat dissipation layer 91 is an inorganic insulating film made of aluminum nitride (AlN) and is deposited by sputtering, vapor deposition, plasma CVD, or other methods. For example, the heat dissipation layer 91 is deposited by sputtering.

The light-emitting element 3 is provided in direct contact with the heat dissipation layer 91. In other words, the light-emitting element 3 is formed by being deposited and patterned on the main surface S1 of the substrate 21, which is a glass substrate, with the heat dissipation layer 91 made of aluminum nitride interposed therebetween as a buffer layer. In other words, the light-emitting element 3 can be fabricated without the process of forming a semiconductor layer (light-emitting element 3) on a sapphire substrate or the like and transferring the light-emitting element 3 onto the substrate 21 using a carrier substrate or the like.

While FIG. 4 illustrates one light-emitting element 3, the description of the light-emitting element 3 illustrated in FIG. 4 can also be applied to the light-emitting elements 3R, 3G, and 3B included in the pixel Pix described above.

The light-emitting element 3 includes a semiconductor layer 31, the anode electrode 32, and the cathode electrode 33 (refer to FIG. 7). The light-emitting element 3 is a light-emitting element in which the anode electrode 32 (p-type electrode) and the cathode electrode 33 (n-type electrode) are provided facing the same direction as the main surface S1 of the substrate 21 (array substrate 2). While the cathode electrode 33 is not illustrated in FIG. 4, it is formed in part of an n-type cladding layer 37 as in the example illustrated in FIG. 7.

As illustrated in FIG. 4, the semiconductor layer 31 of the light-emitting element 3 has a multilayered structure composed of a high resistance layer 38, an n-type cladding layer 37, an active layer 36, and p-type cladding layers 35 and 34. In the light-emitting element 3, the high resistance layer 38, the n-type cladding layer 37, the active layer 36, and the p-type cladding layers 35 and 34 are stacked in order on the heat dissipation layer 91. The anode electrode 32 is provided on the p-type cladding layers 35 and 34.

The semiconductor layer 31 is made of compound semiconductor, such as gallium nitride (GaN), aluminum indium phosphorous (AlInP), indium gallium nitride (InGaN), and aluminum gallium nitride (AlGaN). The semiconductor layer 31 may be made of different materials for the respective light-emitting elements 3R, 3G, and 3B.

The high resistance layer 38 is provided in direct contact with the heat dissipation layer 91. The high resistance layer 38 is made of semiconductor material (e.g., gallium nitride (GaN)) not doped with impurities. The sheet resistance of the high resistance layer 38 is higher than that of the n-type cladding layer 37 stacked thereon.

The n-type cladding layer 37 is made of n-type GaN, for example. The active layer 36 has a multi-quantum well structure (MQW structure) in which well layers and barrier layers composed of several atomic layers are cyclically stacked for higher efficiency. The p-type cladding layer 35 is made of p-type GaN, and the p-type cladding layer 34 is made of p-type aluminum gallium nitride (AlGaN), for example. The anode electrode 32 is provided on the p-type cladding layer 34. The anode electrode 32 has a multilayered structure of titanium (Ti), nickel (Ni), titanium (Ti), and gold (Au), for example.

An element insulating film 39 is provided covering the periphery of the upper surface and the side surfaces of the light-emitting element 3. The element insulating film 39 is an inorganic insulating film for protection and is a silicon oxide film (SiO₂), a silicon nitride film (SiN), or aluminum oxide (Al₂O₃), for example. Alternatively, the element insulating film 39 may be an organic insulating film.

The element insulating film 39 has an opening OP at the position overlapping the anode electrode 32. The anode wiring 23 is provided on an insulating film 96 and is coupled to the anode electrode 32 through the opening OP. The anode electrode 32 is electrically coupled to the drive transistor DRT formed on the substrate 21 (array substrate 2) via the anode wiring 23.

The anode wiring 23 has a multilayered structure of titanium (Ti) and aluminum (Al), for example. The present embodiment is not limited thereto, and the anode wiring 23 may be made of material including one or more of metals of molybdenum and titanium. Alternatively, the anode wiring 23 may be an alloy including one or more of molybdenum and titanium or translucent conductive material.

The cathode electrode 33, which is not illustrated in FIG. 4, is electrically coupled to the cathode wiring 60 via cathode coupling wiring (not illustrated) provided on the insulating film 96. The cathode electrode 33 is made of the same material as that of the anode electrode 32. The coupling structure between the cathode electrode 33 and the cathode wiring 60 may have any desired configuration. For example, the cathode coupling wiring may be provided extending in the first direction Dx and coupled to the cathode electrodes 33 of the light-emitting elements 3 arrayed in the first direction Dx.

The drive transistor DRT and the reset transistor RST are provided in the same layer as that of the light-emitting element 3 on the heat dissipation layer 91. The drive transistor DRT includes a semiconductor layer 61, a source electrode 62, a drain electrode 63, and gate electrodes 64A and 64B. The reset transistor RST includes a semiconductor layer 65, a source electrode 66, a drain electrode 67, and gate electrodes 68A and 68B. FIG. 4 also illustrates a transistor Tr included in the drive circuit 12 provided to the peripheral region GA of the substrate 21.

The following describes the multilayered structure of the drive transistor DRT. Other transistors, such as the reset transistor RST, the transistor Tr, and various transistors illustrated in FIG. 3, have the same configuration, and the description of the drive transistor DRT can be applied to the other transistors.

The gate electrode 64A is provided on the heat dissipation layer 91. An insulating film 92 is provided on the heat dissipation layer 91 and covers the gate electrode 64A. The semiconductor layer 61 is provided on the insulating film 92. An insulating film 93 is provided on the insulating film 92 and covers the semiconductor layer 61. The gate electrode 64B is provided on the insulating film 93. The insulating films 92 and 93 are inorganic insulating films provided between the semiconductor layer 61 and the gate electrodes 64A and 64B to serve as gate insulating films. The insulating films 92 and 93 are silicon nitride films or silicon oxide films, for example.

An insulating film 94 is provided on the insulating film 93 and covers the gate electrode 64B. The insulating film 94 has a multilayered structure of a silicon nitride film and a silicon oxide film, for example. The source electrode 62 and the drain electrode 63 are provided on the insulating film 94. The source electrode 62 is electrically coupled to the semiconductor layer 61 through a contact hole passing through the insulating films 93 and 94. The drain electrode 63 is electrically coupled to the semiconductor layer 61 through a contact hole passing through the insulating films 93 and 94.

An insulating film 95 is an organic insulating film and is provided covering the transistors. The insulating film 95 is made of organic material, such as photosensitive acrylic. The organic material, such as photosensitive acrylic, is excellent in coverability for level difference of wiring and surface flatness compared with inorganic insulating material formed by CVD, for example.

Specifically, the insulating film 95 is provided on the insulating film 94 and covers the source electrode 62 and the drain electrode 63. The insulating film 95 is provided covering the side surfaces of the element insulating film 39 that covers the light-emitting element 3. An anode coupling wiring 24 and a counter electrode 26 are provided on the insulating film 95. The anode coupling wiring 24 is coupled to the source electrode 62 at the bottom of a contact hole formed in the insulating film 95. The counter electrode 26 is coupled to the drain electrode 63 at the bottom of a contact hole formed in the insulating film 95.

The insulating film 96 is provided covering the anode coupling wiring 24 and the counter electrode 26. The insulating film 96 is provided covering the upper surface of the element insulating film 39. The insulating film 96 is an inorganic insulating film and can be made of the same material as that of the insulating films 92 and 93, such as a silicon nitride film. The anode wiring 23 is coupled to the anode coupling wiring 24 at the bottom of a contact hole formed in the insulating film 96. With this configuration, the anode wiring 23 is electrically coupled to the drive transistor DRT.

Part of the anode wiring 23 faces the counter electrode 26 with the insulating film 96 interposed therebetween. The second capacitance Cs2 (refer to FIG. 3) is formed between the anode wiring 23 and the counter electrode 26 facing each other with the insulating film 96 interposed therebetween.

The transistors are formed on the substrate 21 and the heat dissipation layer 91 after the light-emitting element 3 is formed on the substrate 21 and the heat dissipation layer 91. The element insulating film 39 covering the light-emitting element 3 can be formed continuously and integrally with the insulating film 92, which is the gate insulating film, using the same material as that of the insulating film 92. In other words, the element insulating film 39 and the insulating film 92 also function as protective films that protect the light-emitting element 3 in the process of forming the transistors.

The cathode wiring 60 is provided on the insulating film 96 in the peripheral region GA of the substrate 21. The heat dissipation layer 91 is continuously provided on the main surface S1 of the substrate 21 from the region overlapping the light-emitting elements 3 and the transistors (e.g., the drive transistor DRT) in the display region AA to the peripheral region GA and is also provided in the region overlapping the cathode wiring 60.

The insulating films 92 to 95 have contact holes CH1 and CH2 overlapping the cathode wiring 60 and the heat dissipation layer 91 in plan view from the direction perpendicular to the main surface S1 of the substrate 21. More specifically, a heat transfer part 162 is provided in the same layer as that of the source electrode 62 and the drain electrode 63 on the insulating film 94. The heat transfer part 162 is provided by filling the inside of the contact hole CH2 passing through the insulating films 92, 93, and 94 and is in contact with the heat dissipation layer 91 at the bottom of the contact hole CH2.

The cathode wiring 60 is provided by filling the inside of the contact hole CH1 passing through the insulating film 95. In FIG. 4, the part of the cathode wiring 60 provided in the contact hole CH1 is denoted as a heat transfer part 161. The cathode wiring 60 and the heat transfer part 161 are made of the same material and integrally formed. The cathode wiring 60 (heat transfer part 161) is in contact with the heat transfer part 162 at the bottom of the contact hole CH1.

The insulating film 96 is provided covering the insulating film 95 serving as the inner wall surface of the contact hole CH1, and the insulating film 96 and the cathode wiring 60 (heat transfer part 161) are stacked in order on the inner wall surface of the contact hole CH1.

With this configuration, the cathode wiring 60 formed on the insulating film 96 and the heat dissipation layer 91 formed on the main surface S1 of the substrate 21 are coupled through the contact holes CH1 and CH2. The present embodiment is not limited thereto, and one contact hole passing from the insulating film 92 to the insulating film 95 may be formed. The cathode wiring 60 and the heat transfer part 161 may be separately formed. For example, after the heat transfer part 161 is formed to fill the contact hole CH1, the cathode wiring 60 may be provided covering the contact hole CH1 and the heat transfer part 161.

Examples of the material of the cathode wiring 60 (heat transfer part 161) and the heat transfer part 162 include, but are not limited to, titanium (Ti), aluminum (Al), molybdenum (Mo), tantalum (Ta), tungsten (W), niobium (Nb), copper (Cu), carbon nanotube, graphite, graphene, carbon nanobud, silver (Ag), Ag alloy, etc.

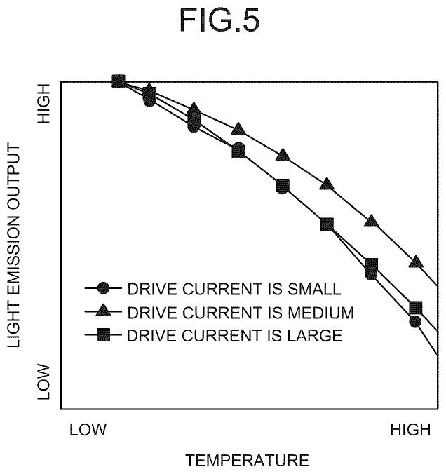

FIG. 5 is a graph of temperature characteristics of an inorganic light-emitting element. The horizontal axis in FIG. 5 indicates the temperature of the light-emitting element 3, and the vertical axis indicates the light emission output of the light-emitting element 3. As illustrated in FIG. 5, the light-emitting element 3 has such a tendency that the light emission output decreases and the light emission operation becomes unstable as the temperature rises. The light-emitting element 3 of any type with small to large drive currents has this tendency.

As illustrated in FIG. 4, the heat dissipation layer 91 made of aluminum nitride is provided between the main surface S1 of the substrate 21 and the light-emitting elements 3 and the transistors and is coupled to the cathode wiring 60 through the contact holes CH1 and CH2 in the peripheral region GA.

The thermal conductivity of the heat dissipation layer 91 made of aluminum nitride is higher than that of the substrate 21, which is a glass substrate. For example, the thermal conductivity of the heat dissipation layer 91 is approximately 285 (W·m⁻¹·K⁻¹) to 320 (W·m⁻¹·K⁻¹). The thermal conductivity of the substrate 21 is approximately 1.5 (W·m⁻¹·K⁻¹) to 1.6 (W·m⁻¹·K⁻¹). The thermal conductivity of the heat dissipation layer 91 made of aluminum nitride is higher than that of the semiconductor layer 31 (GaN) of the light-emitting element 3. The thermal conductivity of GaN is approximately 230 (W·m⁻¹·K⁻¹), for example.

Heat generated by the current flowing through the light-emitting elements 3 is transferred to the heat dissipation layer 91 as indicated by arrow A1. The heat dissipation layer 91 has higher thermal conductivity than the substrate 21 and can efficiently transfer the heat from the light-emitting elements 3 to the cathode wiring 60. As described above, the cathode wiring 60 is provided surrounding the display region AA along the outer periphery of the substrate 21. The thermal conductivity of the cathode wiring 60 and the heat transfer parts 161 and 162 is higher than that of the insulating films 92, 93, 94, 95, and 96 covering the substrate 21. Therefore, the cathode wiring 60 and the heat transfer parts 161 and 162 can efficiently radiate the heat from the light-emitting elements 3 to the outside.

Similarly, the transistors included in the pixel circuit PICA are also provided overlapping the heat dissipation layer 91. The drive transistor DRT, for example, out of the transistors included in the pixel circuit PICA serves as a heat source when a current flows therethrough. The heat generated from the drive transistor DRT is transferred to the heat dissipation layer 91 as indicated by arrow A2. In the same manner as described above, the cathode wiring 60 and the heat transfer parts 161 and 162 can efficiently radiate the heat from the drive transistor DRT.

The configuration described above is given by way of example only and can be appropriately modified. The contact holes CH1 and CH2, for example, are not necessarily formed through the insulating films 92, 93, 94, and 95. The heat dissipation layer 91 and the heat transfer part 162, for example, are not necessarily in direct contact with each other, and an insulating film may be provided between the heat transfer part 162 and the heat dissipation layer 91. While FIG. 1 illustrates four contact holes CH1 in the peripheral region GA, five or more contact holes CH1 may be formed.

As described above, the display device 1 according to the present embodiment includes the substrate 21, the heat dissipation layer 91, the light-emitting elements 3 and the transistors (e.g., the drive transistor DRT), the insulating film 95, and the cathode wiring 60. The heat dissipation layer 91 is provided to the main surface S1 of the substrate 21 and includes aluminum nitride (AlN). The light-emitting elements 3 and the transistors are provided on the heat dissipation layer 91 on the main surface S1 of the substrate 21. The insulating film 95 covers at least the transistors. The cathode wiring 60 is provided on the insulating film 95 in the peripheral region GA outside the display region AA of the substrate 21 and is electrically coupled to the cathode of the light-emitting elements 3. The heat dissipation layer 91 is continuously provided from the region overlapping the light-emitting elements 3 and the transistors to the peripheral region GA. The insulating film 95 has the contact holes CH1 and CH2 overlapping the cathode wiring 60 and the heat dissipation layer 91 in plan view from the direction perpendicular to the main surface S1 of the substrate 21.

### Second Embodiment

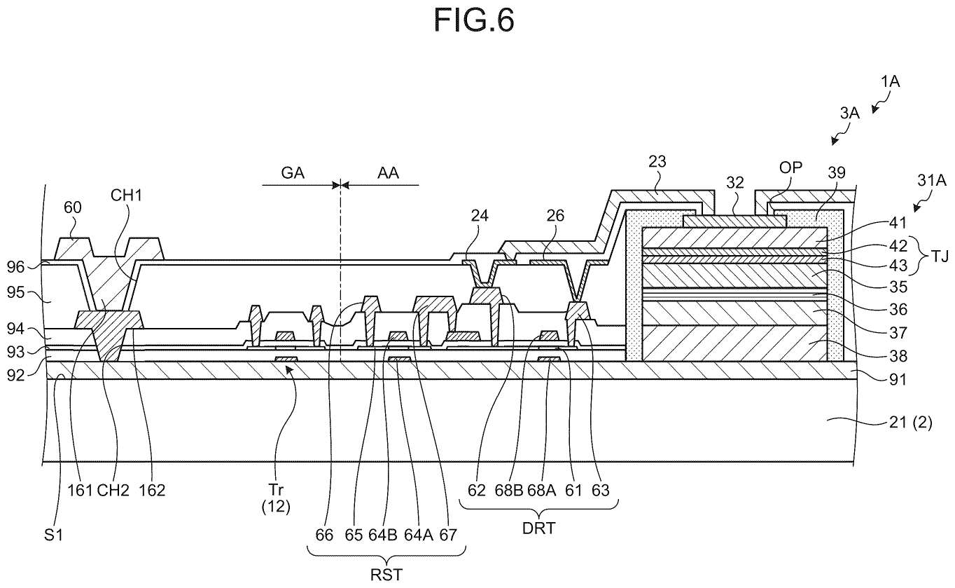

FIG. 6 is a sectional view of a schematic sectional configuration of the display device according to a second embodiment. In the following description, the same components as those described in the embodiment above are denoted by like reference numerals, and overlapping explanation thereof is omitted.

As illustrated in FIG. 6, in a display device 1A according to the second embodiment, a light-emitting element 3A includes a tunnel junction layer TJ stacked on the p-type cladding layer 35. The light-emitting element 3A includes the high resistance layer 38, the n-type cladding layer 37, the active layer 36, the p-type cladding layer 35, the tunnel junction layer TJ, and an n-type cladding layer 41 stacked in order on the heat dissipation layer 91. The tunnel junction layer TJ is composed of a high-concentration p-type semiconductor layer 43 and a high-concentration n-type semiconductor layer 42 formed thinner than the p-type cladding layer 35 and the n-type cladding layer 41. The anode electrode 32 is provided on the n-type cladding layer 41.

In other words, the light-emitting element 3A includes the tunnel junction layer TJ and the n-type cladding layer 41 instead of the p-type cladding layer 34 made of AlGaN of the light-emitting element 3 according to the first embodiment.

With the tunnel junction layer TJ, the light-emitting element 3A has lower resistance than the configuration with the p-type cladding layer 34 made of AlGaN. This is because, in a structure using a cascade LED structure with RGB-LEDs stacked in series in the growth direction, the p-type GaN surface layer is degraded by plasma exposure during dry etching when forming p-type contacts to the lower layer LEDs, whereby hole injection into the LEDs is a major issue as disclosed in T. Wu et al., Appl. Sci. 8, 1557 (2018). By contrast, by replacing the p-type contact of each LED by a tunnel junction (TJ) contact, the tunnel junction layer TJ and the n-type cladding layer 41 are stacked instead of the p-type cladding layer 34. With this configuration, the n-type cladding layer having a larger film thickness and lower sheet resistance is exposed to plasma, thereby solving this problem.

### Third Embodiment

FIG. 7 is a sectional view of a schematic sectional configuration of the light-emitting element according to a third embodiment. As illustrated in FIG. 7, the light-emitting element 3 according to the third embodiment includes a light-emitting element 3B (first light-emitting element) and a light-emitting element 3G (second light-emitting element) adjacent to each other with the element insulating film 39 interposed therebetween. More specifically, the light-emitting element 3B (first light-emitting element) and the light-emitting element 3G (second light-emitting element) are formed on the common high resistance layer 38 provided in direct contact with the heat dissipation layer 91. The light-emitting elements 3B and 3G each include an n-type cladding layer 37G, an active layer 36G, a p-type cladding layer 35G, a tunnel junction layer TJ-G, and an n-type cladding layer 41G stacked in order on the heat dissipation layer 91 and the high resistance layer 38.

A groove is formed between the n-type cladding layer 37G, the active layer 36G, the p-type cladding layer 35G, the tunnel junction layer TJ-G, and the n-type cladding layer 41G of the light-emitting element 3B and the n-type cladding layer 37G, the active layer 36G, the p-type cladding layer 35G, the tunnel junction layer TJ-G, and the n-type cladding layer 41G of the light-emitting element 3G, and the element insulating film 39 is formed in the groove. As a result, the light-emitting element 3B is separated from the light-emitting element 3G.

In the light-emitting element 3G, an anode electrode 32G is provided on the n-type cladding layer 41G, and a cathode electrode 33G is provided on the n-type cladding layer 37G.

In the light-emitting element 3B, an n-type cladding layer 37B, an active layer 36B, a p-type cladding layer 35B, a tunnel junction layer TJ-B, and an n-type cladding layer 41B are further stacked on the n-type cladding layer 41G. An anode electrode 32B is provided on the n-type cladding layer 41B, and a cathode electrode 33B is provided on the n-type cladding layer 41G.

In other words, the height and the number of semiconductor layers of the light-emitting element 3B (first light-emitting element) are different from those of the light-emitting element 3G (second light-emitting element) in the direction perpendicular to the main surface S1 of the substrate 21. More specifically, the height between the anode electrode 32B of the light-emitting element 3B and the high resistance layer 38 is different from that between the anode electrode 32G of the light-emitting element 3G and the high resistance layer 38 in the direction perpendicular to the main surface S1 of the substrate 21.

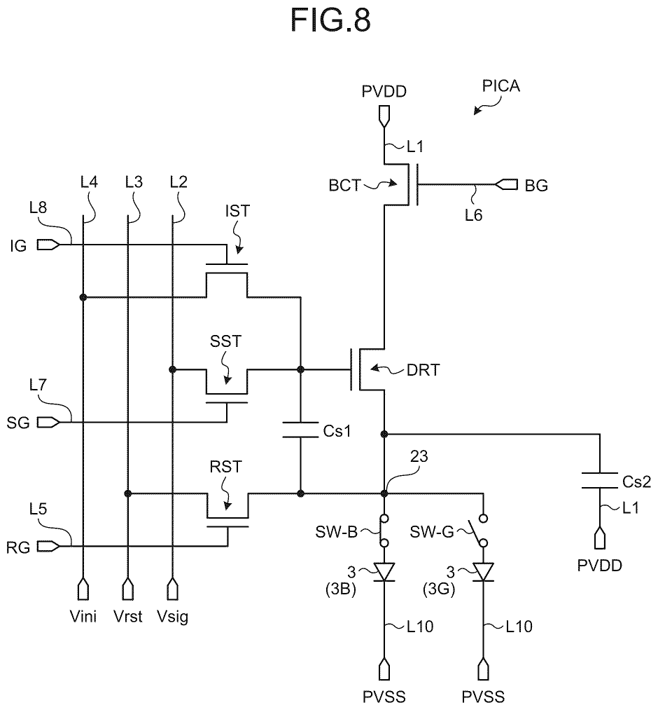

FIG. 8 is a circuit diagram of the pixel circuit according to the third embodiment. As illustrated in FIG. 8, the light-emitting elements 3B and 3G are coupled to the common pixel circuit PICA. The configuration of the pixel circuit PICA is the same as that described above with reference to FIG. 3. The light-emitting elements 3B and 3G according to the present embodiment are coupled to the common drive transistor DRT via switch elements SW-B and SW-G, respectively.

The switch elements SW-B and SW-G operate such that their on/off states are reversed. In a period when one of the light-emitting elements 3B and 3G is coupled to the drive transistor DRT (emission period), the other of the light-emitting elements 3B and 3G is not coupled to the drive transistor DRT (non-emission period). Therefore, the light-emitting elements 3B and 3G are driven in a time division manner by the common pixel circuit PICA.

In the configuration according to the third embodiment, two light-emitting elements 3G and 3B are adjacently formed, and one sub-pixel 49 includes two light-emitting elements 3G and 3B and one pixel circuit PICA. This configuration can reduce the area of the pixels PIX and achieve high-definition display. This configuration can also reduce the number of various transistors and various wiring formed on the array substrate 2.

While exemplary embodiments according to the present invention have been described, the embodiments are not intended to limit the invention. The contents disclosed in the embodiments are given by way of example only, and various modifications may be made without departing from the spirit of the present invention. Appropriate modifications made without departing from the spirit of the present invention naturally fall within the technical scope of the invention. At least one of various omissions, substitutions, and modifications of the components may be made without departing from the gist of the embodiments above and the modifications thereof.

What is claimed is:

1. A display device comprising:
a substrate;
a heat dissipation layer provided to a main surface of the substrate and including aluminum nitride;
a plurality of light-emitting elements provided on the heat dissipation layer on the main surface of the substrate;
an insulating film covering the heat dissipation layer; and
cathode wiring provided on the insulating film in a peripheral region outside a display region of the substrate and electrically coupled to a cathode of the light-emitting elements, wherein
the heat dissipation layer is continuously provided from a region overlapping the light-emitting elements to the peripheral region, and
the insulating film has a contact hole overlapping the cathode wiring and the heat dissipation layer in plan view from a direction perpendicular to the main surface of the substrate.

2. The display device according to claim 1, wherein the light-emitting elements are provided in direct contact with the heat dissipation layer and each comprise a high resistance layer, an n-type cladding layer, an active layer, and a p-type cladding layer stacked in order on the heat dissipation layer.

3. The display device according to claim 2, wherein the light-emitting elements each comprise a tunnel junction layer stacked on the p-type cladding layer.

4. The display device according to claim 1, further comprising:
a plurality of transistors provided on the heat dissipation layer on the main surface of the substrate, wherein
the heat dissipation layer is continuously provided in a region overlapping the light-emitting elements and the transistors in the display region, and
the insulating film covers the transistors.

5. The display device according to claim 4, further comprising:
a gate insulating film provided between a semiconductor layer and a gate electrode of the transistors; and
an element insulating film provided covering a periphery of an upper surface and a side surface of the light-emitting elements, wherein
the gate insulating film and the element insulating film are integrally and continuously formed using common material.

6. The display device according to claim 1, wherein
the light-emitting elements each comprise a first light-emitting element and a second light-emitting element adjacent to the first light-emitting element,
the first light-emitting element and the second light-emitting element are formed on a common high resistance layer provided in direct contact with the heat dissipation layer, and
the height between an anode electrode of the first light-emitting element and the high resistance layer is different from the height between an anode electrode of the second light-emitting element and the high resistance layer in the direction perpendicular to the main surface of the substrate.

7. The display device according to claim 6, wherein the first light-emitting element and the second light-emitting element are coupled to a common transistor via a switch element.

8. The display device according to claim 1, wherein thermal conductivity of the heat dissipation layer is higher than thermal conductivity of the substrate.

9. The display device according to claim 1, wherein the substrate is a glass substrate.
